(19) United States
(12) Patent Application Publication
(10) Pub. No.: US 2017/0032930 A1
(43) Pub. Date: Feb. 2, 2017

(54) METHODS, SYSTEMS AND APPARATUS FOR ACCELERATING LARGE PARTICLE BEAM CURRENTS

(71) Applicant: ISO Evolutions, LLC, Oakwood, TX (US)

(72) Inventor: Matthew Fox Fritz, St. Marys, PA (US)

(21) Appl. No.: 14/967,648

(22) Filed: Dec. 14, 2015

Related U.S. Application Data
(60) Provisional application No. 62/096,186, filed on Dec. 23, 2014.

(51) Int. Cl. H01J 37/317; H05H 5/03

(52) U.S. Cl. CPC H01J 37/3171; H05H 5/03; H01J 2237/31701; H01J 2237/08; H01J 2237/0473

(57) ABSTRACT

Systems and methods for accelerating large particle beam currents in an electrostatic particle accelerator are provided. A system may include a process ion source that is configured to emit ions, a particle accelerator and a target. The particle accelerator may include multiple conductive electrodes that are serially arranged to define a particle path between the process ion source and the target and multiple accelerator tubes arranged to further define the particle path between the process ion source, ones of the conductive electrodes and the target.

### RELATED APPLICATIONS

The present patent application claims priority to U.S. Provisional Application No. 62/096,186; filed Dec. 23, 2014 and entitled Methods And Apparatus For Accelerating Large Particle Beam Currents, the disclosure of which is hereby incorporated herein by reference as if set forth fully herein.

### FIELD OF THE INVENTION

The present invention relates to electrostatic particle accelerators and, more particularly, to methods and apparatus for accelerating large particle beam currents.

### BACKGROUND OF THE INVENTION

Particle accelerators have been a staple for the scientific community since the turn of the 20^{th} century. The need to go beyond the energy limit of natural radioactive sources (alpha/beta emitters) drove the invention and innovation of particle accelerators leading to the original competing technologies of electrostatic and induced alternating field accelerators. The need to continually increase the energy capabilities, coupled with the limits of original electrostatic accelerators, has lead to induced alternating field accelerators becoming a dominate technology of the past 50 years.

As both electrostatic and induced alternating field accelerators have been used as tools for precision and discovery, the need to accelerate large particle beams currents (100s of mA and greater) has not been of significant concern. As particle accelerator technology is transitioning from the previous applications of scientific research and becoming an industrial tool for varied applications, the need to accelerator large particle beam currents in a cost effective yet accurate manner may become increasingly important.

An early practical electrostatic particle accelerator was developed in 1929 at Princeton University by Robert Van de Graaff. Van de Graaff's machine consisted of a power source to “spray” charge carriers onto an insulating belt that would then be transported to the interior of a hollow conducting sphere. Inside the hollow conducting sphere, a spray comb neutralized the charges on the belt and developed a positive voltage on the conducting sphere. This voltage was then used to accelerate particles emitted from an ion source. Attempts to build larger machines with higher voltages were limited by the dielectric breakdown strength of air (˜3 MV/m). To overcome this problem, the conducting medium was placed in a pressure tank and flooded with pressurized gas to achieve higher potentials (up to 25 MV).

Induced alternating electric field accelerators were first constructed in 1928 by Rolf Wideroe from Norway. In induced alternating electric field accelerators, an RF source induces an alternating sign electric field within an evacuated cavity that is used for acceleration. Due to the alternating nature of the field, the particles need to be shielded from the field when the polarity is opposite that which is needed for acceleration. This principle gave rise to other accelerator types still in use today. Examples of such alternating electric field accelerators include the radiofrequency quadrupole (RFQ), cyclotron, and synchrotron.

Both electrostatic and induced alternating field accelerators may be currently limited in the amount of particle beam current that can be accelerated thereby. Electrostatic systems may be limited because the methods of charging the system to the high operating voltage is limited to a few mAs maximum for the largest machines. Induced alternating electric field accelerators may be limited due to the large RF power source that may be required. Conventional accelerator beam current limitations may prove to be unsuitable as new applications requiring large beam currents of accelerated particles arise.

### BRIEF DESCRIPTION OF THE DRAWINGS

FIG. 1 is a schematic diagram of a single unit high current particle accelerator according to some embodiments of the present invention.

FIG. 2 is a cross-sectional schematic diagram of a high current particle accelerator including a charging system and voltage stabilization system according to some embodiments of the present invention.

FIG. 3 is a flowchart illustrating operations according to some methods according to some embodiments of the present invention.

FIG. 4 is a schematic diagram of a single unit high current particle accelerator according to some embodiments of the present invention.

FIG. 5 is a schematic diagram of a single unit high current particle accelerator including a charging chain according to some embodiments of the present invention.

FIG. 6 is a schematic diagram of a high current particle accelerator system that includes multiple high current particle accelerator units according to some embodiments of the present invention.

FIG. 7 is a schematic diagram of a high current particle accelerator system that includes multiple high current particle accelerator units and a comparative graph illustrating the acceleration field as a function of position relative to the multiple high current particle accelerator units according to some embodiments of the present invention.

FIG. 8 is a schematic diagram of a high current particle accelerator system that includes multiple high current particle accelerator units in a non-linear arrangement according to some embodiments of the present invention.

### SUMMARY OF THE INVENTION

Some embodiments of the present invention are directed to systems, methods and apparatus for accelerating large particle beam currents in an electrostatic particle accelerator. Systems according to such embodiments may include a process ion source that is configured to emit ions, a particle accelerator, and a target. In some embodiments, the particle accelerator includes a conductive electrode that includes an interior space and that is configured to be charged to a high-voltage electrical potential, a first charging device that is configured to deliver a charging current to the conductive electrode to charge the conductive electrode to a given polarity and a given magnitude, a second charging device that is configured to generate a voltage stabilizing current to the conductive electrode that corresponds to an ion current of the process ion source that is within the interior space of the conductive electrode, and an accelerator tube positioned between the process ion source and the target and that includes a particle receiving end that is galvanically coupled to the conductive electrode and a particle exit end that is opposite the particle receiving end and that is galvanically coupled to a negative ion or electron source. Some embodiments provide that the particle accelerator accelerates the ions emitted from the process ion source to produce accelerated ions that bombard the target.

In some embodiments, the conductive electrode comprises a hollow metal shell and the negative ion or electron source comprises an earth ground.

Some embodiments provide that the accelerator tube comprises multiple step voltage divider that divides adjacent portions thereof into sections, each section having a reduced voltage in the direction towards the exits end of the accelerator tube.

Some embodiments provide that the first charging device comprises a charging chain that comprises a plurality of conductive pellets that are linked to one another by a plurality of non-conducting links.

In some embodiments, the first charging device comprises a charging ion source that is configured to emit ions to provide the charging current to charge the conductive electrode. Some embodiments provide that the first charging device further comprises an ion implantation target that is positioned within the conductive electrode and that is configured to receive the ions emitted from the stabilization ion source. In some embodiments, the ion implantation target is galvanically coupled to the conductive electrode.

Some embodiments provide that the second charging device comprises a stabilization ion source that is configured to emit ions responsive to the conductive electrode being charged by the first charging device. In some embodiments, the second charging device further comprises a stabilization ion implantation target that is positioned within the conductive electrode and that is configured to receive the ions emitted from the stabilization ion source. Some embodiments provide that the stabilization ion implantation target is galvanically coupled to the conductive electrode. In some embodiments, the second charging device further comprises a conductive element that is conductively coupled between an interior surface of the conductive electrode and the ion implantation target and charges flow from the conductive electrode to the ion implantation target via the conductive element responsive to the ion implantation target the ions from the stabilization ion source. Some embodiments provide that the conductive element comprises a conductive wire and/or carbon brushes.

In some embodiments, the second charging device further comprises a stabilization ion transport volume that is between the stabilization ion source and the ion implantation medium and that is configured to provide a transport path for the ions from the stabilization ion source to the ion implantation medium. Some embodiments provide that the ion transport volume comprises a structure that defines an evacuated space between the stabilization ion source and the ion implantation medium.

Some embodiments of the present invention are direct to an apparatus that includes a conductive electrode that includes an interior space and that is configured to be charged to a high-voltage electrical potential, a first charging device that is configured to deliver a charging current to the conductive electrode to charge the conductive electrode to a given polarity and a given magnitude, a second charging device that is configured to generate a voltage stabilizing current to the conductive electrode that corresponds to an ion current of a process ion source that is within the interior space of the conductive electrode, a conductive electrode receiving portion that is configured to be coupled to a first accelerator tube via a galvanically insulating structure that is operable to galvanically insulate the conductive electrode receiving portion from the first accelerator tube, and a conductive electrode transmitting portion that is configured to be galvanically coupled to a second accelerator tube that is arranged opposite the conductive electrode receiving portion.

In some embodiments, the conductive electrode receiving portion is configured to receive atomic particles and the conductive electrode transmitting portion is configured to transmit atomic particles.

Some embodiments provide that the second charging device comprises a stabilization ion source that is positioned within an interior of the conductive electrode and that is configured to emit ions responsive to the conductive electrode being charged by the first charging device, an ion implantation target that is configured to receive the ions emitted from the stabilization ion source, an ion transport volume that is between the stabilization ion source and the ion implantation medium and that is configured to provide a transport path for the ions from the stabilization ion source to the ion implantation medium, and a conductive element that is conductively coupled between an interior surface of the conductive electrode and the ion implantation target.

Some embodiments of the present invention are directed to a system including a process ion source that is configured to emit ions, a particle accelerator, and a target. Some embodiments provide that the particle accelerator comprises a plurality of conductive electrodes that are serially arranged to define a particle path between the process ion source and the target and a plurality of accelerator tubes arranged to further define the particle path between the process ion source, ones of the plurality of conductive electrodes and the target.

In some embodiments, ones of the plurality of conductive electrodes include an interior space and are configured to be charged to a high-voltage electrical potential. Some embodiments further include within ones of the plurality of conductive electrodes, a first charging device that is configured to deliver a charging current to the respective one of the plurality of conductive electrodes to charge the respective one of the plurality of conductive electrodes to a given polarity and a given magnitude and a second charging device that is configured to generate a voltage stabilizing current to the respective one of the plurality of conductive electrodes that corresponds to an ion current of a stabilizing process ion source that is within the interior space of the respective one of the plurality of conductive electrodes.

In some embodiments, the plurality of conductive electrodes includes a first conductive electrode and a second conductive electrode, the plurality of accelerator tubes includes a first accelerator tube and a second accelerator tube, the first conductive electrode includes an interior space that is configured to include the process ion source, the first accelerator tube includes is arranged between the first conductive electrode and the second conductive electrode, and the second accelerator tube is galvanically coupled to the second conductive electrode.

Some embodiments provide that the first accelerator tube is galvanically coupled to the first conductive electrode and is coupled to the second conductive electrode via a first insulator.

In some embodiments, the plurality of conductive electrodes includes a third conductive electrode and the second accelerator tube is coupled to the third conductive electrode via a second insulator.

Some embodiments provide that ones of the plurality of conductive electrodes are configured to be charged to a high-voltage electrical potential, and the high-voltage electrical potential is sustainable in free space based on a dielectric constant corresponding to air.

Some embodiments of the present invention are directed to methods that include providing a charging current to a conductive electrode in a high current particle accelerator system using a charging ion source, and providing a voltage stabilization current to the conductive electrode using a stabilization ion source that is different from the charging ion source.

In some embodiments, the charging current comprises a current in a range from about 1 μA to about 1500 μA, and the voltage stabilization current comprises a current in a range of 1 A to about 100 A.

It is noted that aspects of the invention described with respect to one embodiment, may be incorporated in a different embodiment although not specifically described relative thereto. That is, all embodiments and/or features of any embodiment can be combined in any way and/or combination. These and other objects and/or aspects of the present invention are explained in detail in the specification set forth below.

Further features, advantages and details of the present invention will be appreciated by those of ordinary skill in the art from a reading of the figures and the detailed description of the preferred embodiments that follow, such description being merely illustrative of the present invention.

### DETAILED DESCRIPTION

The present invention now will be described more fully hereinafter with reference to the accompanying drawings, in which illustrative embodiments of the invention are shown. In the drawings, the relative sizes of regions or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element is referred to as being “coupled” or “connected” to another element, it can be directly coupled or connected to the other element or intervening elements may also be present. In contrast, when an element is referred to as being “directly coupled” or “directly connected” to another element, there are no intervening elements present. Like numbers refer to like elements throughout.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein the expression “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this disclosure and the relevant art and will not be interpreted in an idealized or overly formal sense unless expressly so defined herein.

In an electrostatic system, voltage may typically be created from a deficiency (positive polarity) or excess (negative polarity) of electrons in accordance with the following equation:

Q=C*V;

where Q is the magnitude of deficiency or excess of charge, V is the voltage, and C is the capacitance of the system. Although voltage may be manipulated via geometric and/or material parameters, voltage may not be induced without a lack of or excess of charge carriers.

Low charging current in positive electrostatic accelerator systems may be alleviated by creating the same deficiency of charge carriers, which may be accomplished by adding positive charge carriers to the electrostatic accelerator system rather than removing negative charge carriers. Adding positive charges may be accomplished using an ion source that emits positively charged ions to become part of the electrostatic accelerator system. This may be viewed as maintaining the same amount of negative charge carriers and varying the quantity of positive charge carriers.

The same effect may be accomplished for negative polarity systems by introducing negatively charged ions as either free electrons or atoms including an excess of electrons to the electrostatic accelerator system.

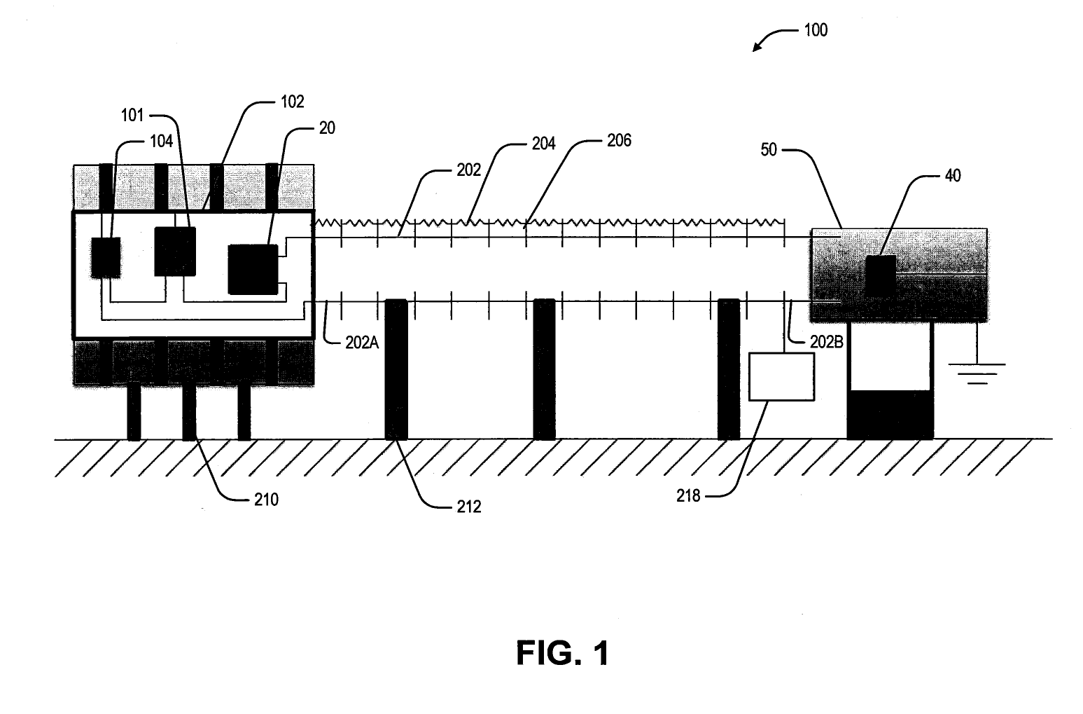

Reference is now made to FIG. 1, which is a schematic diagram of an electrostatic accelerator according to some embodiments of the present invention. The electrostatic accelerator 100 includes an electrically conductive electrode 102, which may function as a high-voltage terminal. In some embodiments, the conductive electrode 102 may be a cylindrical hollow electrode made of a conductive material. In some embodiments that conductive electrode includes a coaxial cylinder, a sphere, concentric spheres or other geometries that may provide substantial Gaussian surfaces. Some embodiments provide that the conductive material is stainless steel, however, the invention is not so limited in that the conductive material may include any of a number of ferrous and/or nonferrous metals and/or combinations thereof. A high voltage stabilization system 101 may be included within the cavity defined by the conductive electrode 102.

In some embodiments, the conductive electrode 102 is electrically shielded, however, such embodiments are not limiting. The conductive electrode 102 may be arranged such that a dielectric material is between the conductive electrode and a shielding structure. Some embodiments provide that the dielectric is a solid dielectric material, a pressurized gas and/or free air at atmospheric pressure.

In use and operation, the conductive electrode 102 is charged to a high positive electric potential (e.g., hundreds of thousands to millions of volts) by an electrode charging system 104. In some embodiments, the electrode charging system 104 may include a charging chain formed of conducting pellets and insulating links attaching adjacent pellets to one another. Some embodiments provide that the charging chain includes conducting metal pellets linked together using insulating nylon links, however such embodiments are nonlimiting examples.

To sustain the high voltages that may be produced on the conductive electrode 102, portions of the charging system including the conductive electrode 102 may be contained within a pressure tank that may be pressurized with an insulating gas, such as, for example, sulfur hexafluoride, carbon dioxide and/or nitrogen, among others. However, some embodiments described herein may include multiple conductive electrodes, each configured to be charged to voltages that may be sustained in free air based on the dielectric properties of air to reduce the need for such specialized environments. In embodiments including multiple conductive electrodes 102, the operating voltages may be the same and/or different from one another.

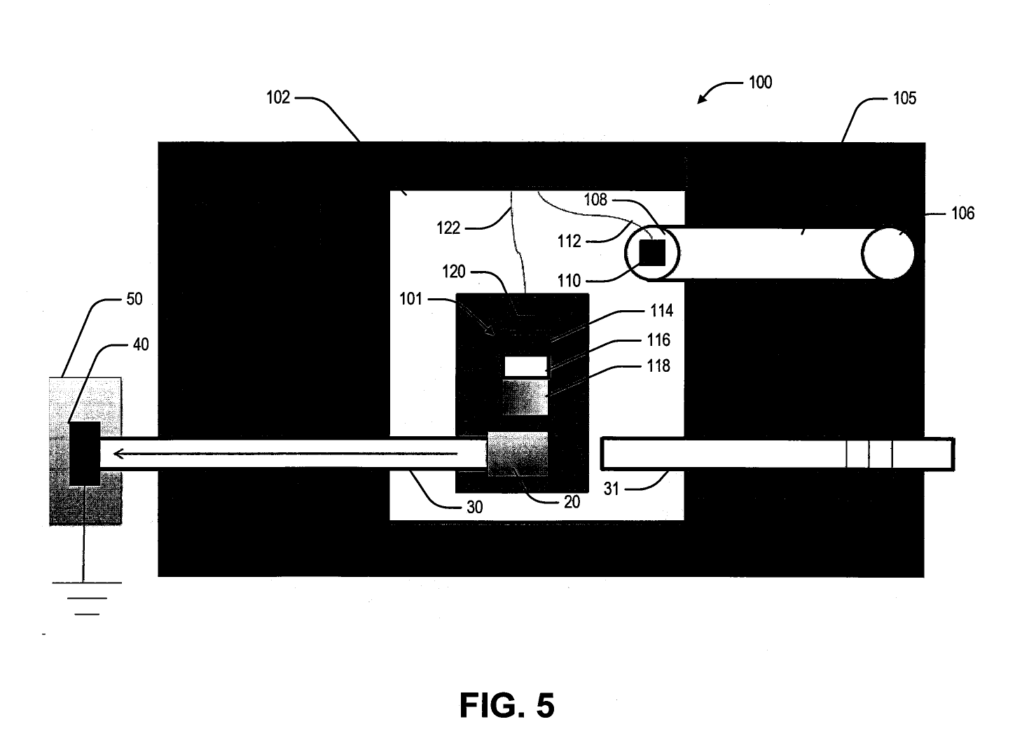

Electrostatic accelerator charging systems may operate on the principle that the electric field inside a hollow conductor is zero such that charges delivered to the interior of a hollow conductor will orient themselves on the outer surface of the conductor. Brief reference is now made to FIG. 5, which is a schematic diagram of a single unit high current particle accelerator that is adapted to be used to increase the beam current in conventional low particle beam current electrostatic particle accelerators including a charging chain according to some embodiments of the present invention.

As used herein, the electrode charging system 104 may include a charging chain 105 including metal pellets that are connected to insulating nylon links are wrapped around two pulleys. One of the pulleys is a drive pulley 106 and the other pulley is a terminal pulley 108 that is located within the conductive electrode 102. As the electrode charging chain 105 rotates around on the drive pulley 106, electrical charges are induced on the individual pellets by electrodes that are connected to a power supply. In some embodiments, the power supply is a high voltage power supply capable of delivering power at voltages that range from 10 kV to about 100 kV. For example, the high voltage power supply may deliver be capable of providing power at 10 kV, 20 kV, and/or 50 kV, among others.

As the charging chain moves, charged pellets move from the drive pulley 106 to the terminal pulley 108 that is inside and connected to the conductive electrode 102. The conductive electrode 102 develops a large positive electric potential by transferring the electrons from its outer surface to neutralize the charges on the pellet through the terminal pulley 108. The charging current may be transferred from the terminal pulley 108 to the conductive electrode 102 using brushes 110 and connecting wires 112. Some embodiments provide that the charging system may deliver relatively small current (e.g., about 150 μA) to the conductive electrode 102 per charging chain 104. The relatively small current may only be capable of sustaining the development of high-voltage on the conductive electrode 102 in the transport of a small amount of beam current, such as 10 to 100 μA continuous or 10 to 100 mA when pulsed. Although multiple charging chains 104 may be used within a charging system, some applications of the electrostatic accelerator 100 may require significantly more current, such as, for example, 1 A or greater.

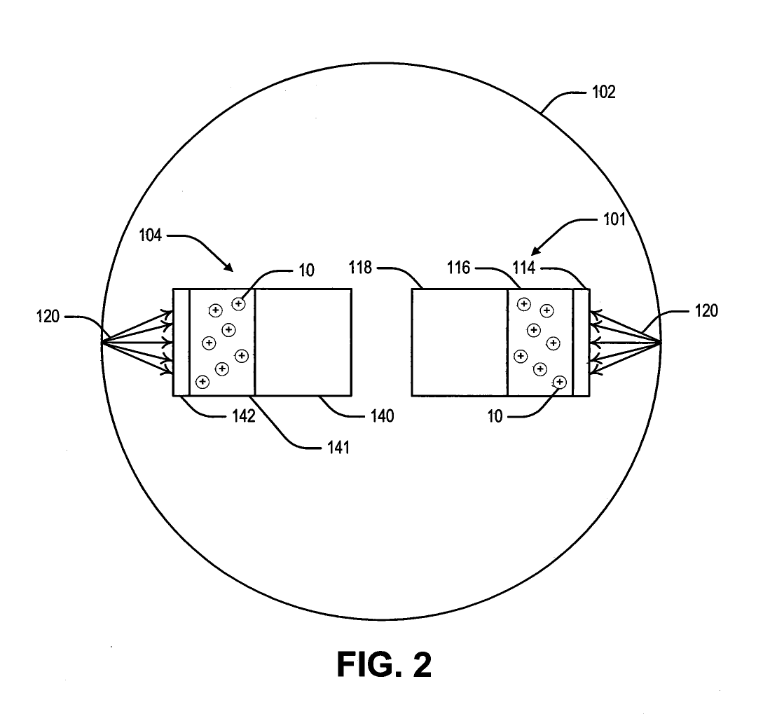

Reference is now made back to FIG. 1 and to FIG. 2, which is a cross-sectional schematic diagram of a high current particle accelerator including a charging system and voltage stabilization system according to some embodiments of the present invention. Some embodiments provide that the electrode charging system 104 includes a charging ion source 140 and a charging implantation medium 142 that are positioned within the cavity defined by the conductive electrode 102. As disclosed herein, the charging ion source 140 and the charging implantation medium 142 may be mounted inside the conductive electrode 102 of the electrostatic accelerator. In some embodiments, a charging ion transport volume 141 may be provided between the charging ion source 140 and the charging implantation medium 142.

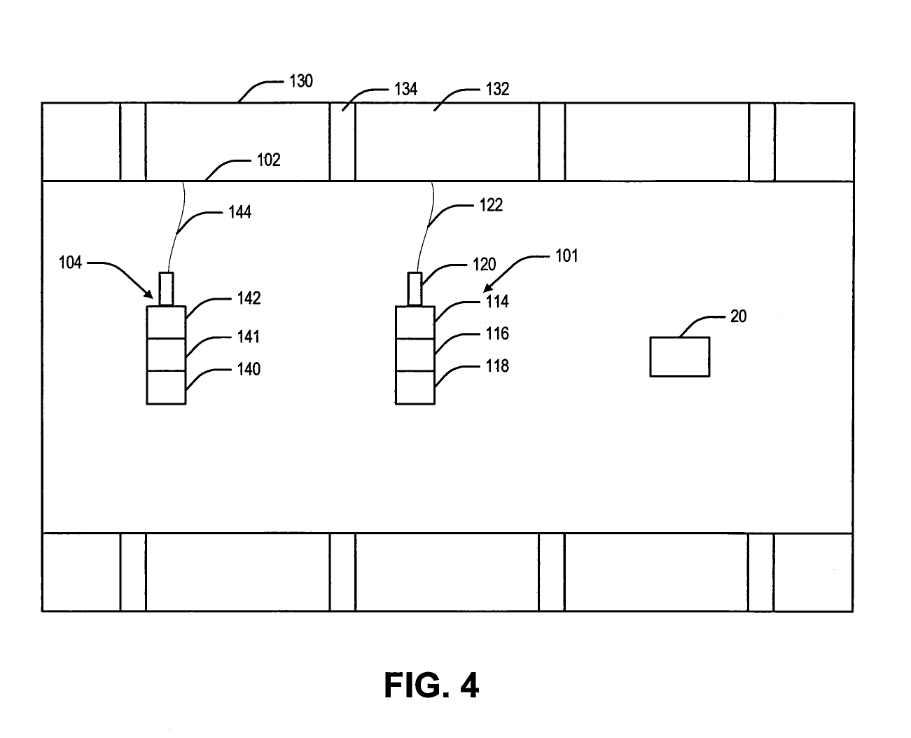

The charging ion source 140 may be positioned within the conductive electrode 102 and may produce positively charged ions at some portion of the final beam current level that is to be transported by the electrostatic accelerator. The positively charged ions may traverse the charging ion transport volume 141 and may be delivered to the charging implantation medium 142. In some embodiments, the charging ion transport volume 141 may include a vacuum or other similarly evacuated space. The charging implantation medium 142 may be conductively connected to the conductive electrode 102 via one or more conductive elements (144, FIG. 4). For example, in some embodiments the conductive elements (144, FIG. 4) may include carbon brushes and/or wires or other conductive components to provide a conductive path between the charging implantation medium 144 and the conductive electrode 102.

As the positively charged ions become implanted into the charging implantation medium 142, positive charge develops in the charging implantation medium 142. As the positive charge develops, the conductive electrode 102 gives up electrons through the conductive elements 144 to neutralize the positive charge built up in the charging implantation medium 142. The transfer of the electrons from the conductive electrode results in a net increase in positive charge thereon. In this manner, the conductive electrode 102 is charged by the charging ion source 140 to provide an initial voltage capable of delivering a beam of charged particles. Although some embodiments include an implantation medium for receiving the charged ions, some embodiments may provide that the charge carriers may be introduced to the conductive electrode 102 by direct application to the interior of the conductive electrode (i.e., direct implantation).

In order to achieve conditions for high beam current transport, the electrostatic accelerator 100 may include a high voltage stabilization system 101 that includes a stabilization ion source 118. In this manner, some embodiments include three ion sources for modified ion implantation for beam transport and stabilization. The first ion source may be the process ion source 20 that generates the beam to be delivered to the target 40. The second ion source may be the charging ion source 140, which may provide the voltage stabilization of the conductive electrode 102. The third ion source may be the stabilization ion source 118, which may provide the voltage stabilization of the conductive electrode 102.

In order to achieve conditions for stable high-voltage on the conductive electrode 102 and high beam current transport, the high voltage stabilization system that includes the stabilization ion source 118 may provide the voltage stabilization of the conductive electrode 102. Ion implantation may use the stabilization ion source 118 to accelerate and “implant” low-energy ions onto the stabilization implantation medium 114 creating a net positive charge on the stabilization implantation medium 114 that is then neutralized by various techniques. As disclosed herein, the stabilization ion source 118 and stabilization implantation medium 114 may be mounted inside the conductive electrode 102 of the electrostatic accelerator to overcome the limitations of beam current transport. In some embodiments, a stabilizing ion transport volume 116 may be provided between the stabilization ion source 118 and the stabilization implantation medium 114.

In some embodiments of the present invention, an electrostatic accelerator 100 may also include an accelerator beam tube 202 that includes a series of insulators and electrodes that are bonded together to form a voltage divider to transport a beam of charged particles. Some embodiments provide that the individual electrodes 206 may be linked together with large resistance value resistors 204, such as, for example, 1 gigaohm resistors, to limit the current that is drawn from the high voltage conductive electrode 102.

The electrostatic accelerator 100 may include a process ion source 20 and one or more accelerator beam tubes 202. Some embodiments may provide that accelerator beam tube 202 is configured to transfer the beam to beam target 40 that may be grounded and located within a target chamber 50. The accelerator beam tube 202 may include a receiving end 202A and a transmitting end 202B that is opposite the receiving end 202A. A particle beam is received at the receiving end 202A and transmitted from the transmitting end 202B.

The receiving end 202A may be galvanically coupled to a conductive electrode 102 and the transmitting end may be galvanically coupled to a negative ion or electron source 218. In some embodiments, the negative ion or electron source 218 may include, for example, an electrical (earth) ground. In such embodiments, the earth ground may be used to provide an inexpensive charge donor. Although not illustrated, some embodiments provide that all or a portion of the electrostatic accelerator 100 may be positioned within a cavity of the negative ion or electron source 218, such as, for example, in a generally coaxial arrangement. Some embodiments provide that such arrangement may be used under conditions in which an electrical earth ground is unavailable. For example, an electrostatic accelerator 100 that is operated extra-terrestrially, such as in an airborn or satellite application, may use the negative ion or electron source 218 to provide the necessary charge to the conductive electrode 102. For example, some embodiments herein may be used in satellite-based ion thrusters in which ion streams are used to generate thrust for the satellite.

As used herein, the term galvanically coupled may refer to an electrical conductive coupling. The voltage divider circuit along the accelerator beam tube 202 may provide that, when the conductive electrode is charged to an operating voltage, the individual electrodes 206 have decreasing voltage levels along the accelerator beam tube 202 toward the transmitting end 202B. The accelerator beam tube 202 in contact with the high voltage conductive electrode 102 and the negative ion or electron source (e.g., ground connection) 218 may provide a substantially stable, constant acceleration field.

In some embodiments, the conductive electrode 102 may be structurally supported by one or more insulating electrode structures 210 to support the conductive electrode and the contents therein while providing electrical insulation from the ground. Similarly, the accelerator beam tube 202 may be structurally supported by one or more insulating tube support structures 212.

Referring to FIG. 2, the charging ion source 140 may be positioned within the conductive electrode 102 and may produce positively charged ions 10. The positively charged ions 10 may traverse a charging ion transport volume 141 and may be delivered to the charging implantation medium 142. In some embodiments, the charging ion transport volume 141 may include a vacuum or other similarly evacuated space. The charging ion transport volume 141 may be conductively connected to the conductive electrode 102 via one or more conductive elements 120. For example, in some embodiments the conductive elements 120 may include carbon brushes and/or wires or other conductive components to provide a conductive path between the charging implantation medium 142 and the conductive electrode 102.

As the positively charged ions 10 become implanted into the charging implantation medium 142, positive charge develops in the charging implantation medium 142. As the positive charge develops, the conductive electrode 102 gives up electrons through the conductive elements 120 to neutralize the positive charge built up in the charging implantation medium 142. The transfer of the electrons from the conductive electrode 102 results in a net increase in positive charge thereon.

The stabilization ion source 118 may be positioned within the conductive electrode 102 and may produce positively charged ions 10 at or above the beam current level that is to be transported by the electrostatic accelerator. The positively charged ions 10 may traverse an ion transport volume 116 and may be delivered to the stabilization implantation medium 114. In some embodiments, the ion transport volume 116 may include a vacuum or other similarly evacuated space. The ion implantation medium may be conductively connected to the conductive electrode 102 via one or more conductive elements 120. For example, in some embodiments the conductive elements 120 may include carbon brushes and/or wires or other conductive components to provide a conductive path between the stabilization implantation medium 114 and the conductive electrode 102.

Similar to the charging operations described above, as the positively charged ions 10 become implanted into the stabilization implantation medium 114, positive charge develops in the stabilization implantation medium 114. As the positive charge develops, the conductive electrode 102 gives up electrons through the conductive elements 120 to neutralize the positive charge built up in the stabilization implantation medium 114. The transfer of the electrons from the conductive electrode 102 may result in a net increase in positive charge thereon. In this manner, the conductive electrode 102 is charged by both the electrode charging system 104 and the stabilization ion source 118 to provide a stabilized voltage capable of delivering the near continuous beam of charged particles.

As used herein, the conductive electrode 102 may be referred to as a high-voltage terminal. Electrostatic accelerator voltage stabilization may be based on the equation expressing that the rate of change of terminal voltage with respect to time equals the difference between the charging current and the depletion current, divided by the capacitance of the terminal.

$$\frac{d {V}_{t}}{d t} = \frac{1}{{C}_{t}} ( {I}_{ch} - {I}_{beam} - {I}_{lost} - \frac{{V}_{t}}{R} ) ;$$

where:

Vₜ is the terminal voltage;

Cₜ is the terminal capacitance;

I_{ch} is the current from the charging system;

I_{Beam} is the current transported by the accelerator;

I_{Lost} is the current lost to the environment and/or medium; and

Vₜ/R is the leakage current down the terminal support system.

The term I_{Standard} may be defined as I_{ch}−Iₗₒₛₜ−Vₜ/R such that the equation becomes:

$$\frac{d {V}_{t}}{d t} = \frac{1}{{C}_{t}} ( {I}_{standard} - {I}_{beam} ) .$$

For a stable voltage on the high voltage terminal, the rate of change of voltage equals zero and thus I_{standard}=I_{Beam}.

Based on the above, the introduction of a new source for charging can allow I_{Beam} to be greater than I_{Standard} while the rate of change of voltage remains zero. A new source I_{New} may be defined and supplied by the stabilization ion source 118. The stabilization ion source 118 may be directed at a material shape to implant ions in, which is referred to herein as the stabilization implantation medium 114. The charge in the stabilization implantation medium 114 may be neutralized via connections to the high-voltage terminal. In this regard, the equation becomes:

$$\frac{d {V}_{t}}{d t} = \frac{1}{{C}_{t}} ( {I}_{standard} + {I}_{new} - {I}_{beam} ) .$$

Still using the assumption that the rate of change of terminal voltage is zero, then:

I_{Standard}+I_{New}=I_{Beam}.

In some embodiments, the stabilization ion source 118 and/or the charging ion source 140 may include an electron cyclotron resonance ion source operating at microwave frequencies to provide singly charged ions with high intensities. Some embodiments provide that the stabilization ion source 118 and/or the charging ion source 140 use an ionization method in which energetic electrons interact with gas phase atoms or molecules to produce ions. Some embodiments provide that the stabilization ion source 118 and/or the charging ion source 140 may include a solid-state ion source. The process medium for the stabilization ion source 118 and/or the charging ion source 140 may be any type of medium and may be used in whichever physical state may be necessary. Some embodiments provide that the stabilization ion source 118 and/or the charging ion source 140 may be able to produce ions with equivalent charge state output to that of the beam current desired to be accelerated.

In some embodiments, the stabilization implantation medium 114 and/or the charging implantation medium 142 may be a solid plate and may include a generally circular shape, although the present disclosure is not limited thereto. In some embodiments, a hollow cylinder that is partially bored through may be used as the stabilization implantation medium 114 and/or the charging implantation medium 142. Some embodiments provide that the stabilization implantation medium 114 and/or the charging implantation medium 142 may be a suitable conductor such as copper, aluminum, stainless steel and/or graphite, among others.

As disclosed herein, the conductive electrode 102 is charged by charging system including at least the charging ion source 140 and the stabilization system including at least the stabilization ion source 118. Some embodiments provide that the charging system is configured to charge the conductive electrode 102 based on a charging current in a range of about 1 μA to about 150 μA. In contrast, some embodiments provide that the stabilization system is configured to maintain the operating potential (voltage) of the conductive electrode 102 by providing a stabilization current in a range of 0.1 A to about 100 A. For example, the limit of the stabilization current is based on the limit of the stabilization ion source current.

In some embodiments, the stabilization ion source 118 and/or the charging ion source 140 may reside outside the conductive electrode 102. In such embodiments, however, the stabilization implantation medium 114 and the charging implantation medium 142 reside within the interior of the conductive electrode 102 for the conductive electrode 102 to neutralize the applied charge.

The conductive element 120 may include one or more carbon brushes, one or more conducting wires between the stabilization implantation medium 114/charging implantation medium 142 and the conductive electrode 102, and/or a sputtering comb, brush and/or screen, among others.

Some embodiments provide that the stabilization implantation medium 114 and the charging implantation medium 142 are positioned sufficiently far from the stabilization ion source 118 and the charging ion source 140, respectively, to prevent electrical arcing between the two components.

Embodiments of the present invention may be used with current tandem electrostatic accelerators using both the low-energy end (negative ion injection to charge stripping) and high-energy end (charge stripping leaving positively charged ions and subsequent acceleration to grounded target). In such cases, the stabilization ion source 118 may produce charged particles with current corresponding to:

I_{Beam tandem}=I_{Low energy}+I_{High energy}.

Although discussed herein in terms of positively charged particle transport, systems and methods disclosed herein may be used for transport of large currents of electron beams as well. In such cases the stabilization ion source 118 and charging ion source 140 would produce electrons to be implanted into the stabilization implantation medium 114 and charging implantation medium, respectively.

Some embodiments disclosed herein may be applied to radioisotope production for medicine, industry and commercial interests, for ion implanters in semiconductor manufacture, to provide electron beams for X-ray inspection of welds, for nuclear fusion, neutral beam injectors, and heavy ion fusion, for nuclear waste transmutation, spent nuclear fuel reuse as a subcritical assembly, to manufacture Pu-238 for space travel power systems, for ion beam therapy, for local position emission therapy isotope production, and/or to provide cost efficient variable particle accelerators for general scientific research, among others.

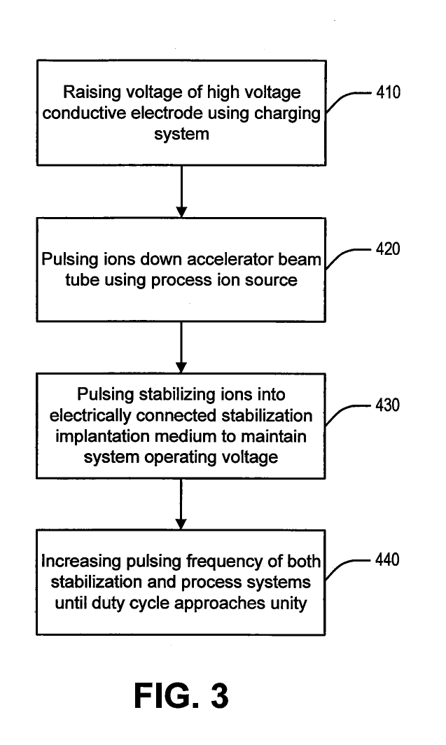

Reference is now made to FIG. 3, which is a flowchart illustrating operations according to some methods according to some embodiments of the present invention. Some embodiments include raising the voltage of a hollow conductive electrode of an electrostatic particle accelerator using a charging system (block 410). For example, a charging chain including charge carrying pellets may be used to transport charge from outside the conductive electrode to an interior of the conductive electrode. Some embodiments provide that the charging system includes an ion source and corresponding implantation medium that are inside the hollow conductive electrode. In this manner, the desired polarity and magnitude of voltage in the conductive electrode may be attained.

Ions are pulsed down the accelerator beam tube using a process ion source that is inside the hollow conductive electrode (block 420). At or near the process of the ions being emitted from the process ion source, stabilizing ions may be pulsed into an electrically connected stabilization implantation medium to maintain the operating voltage of the conductive electrode (block 430). As discussed above, a stabilization ion source may generate ions to be received by the stabilization ion implantation target. The stabilization ion implantation target may be conductively coupled to the conductive electrode and may receive opposite charges from the conductive electrode to neutralize the received ions. In this manner, additional charge is generated on the surface of the conductive electrode. In some embodiments, the stabilization ion source and implantation medium pulse substantially the same current as the process ion source.

The high voltage terminal free charge carriers (e.g., electrons) in the conductive electrode may reorient themselves such that there is no electric field inside the conductive electrode and that the charge resides only on the surface of the terminal, in accordance with Gauss' law.

The pulsing frequency of the process ion source and the stabilization ion source is increased until the duty cycle of the system approaches unity and the conductive electrode is stable at the desired magnitude (block 440). While illustrated in FIG. 1 as including a single accelerator unit, embodiments herein may appreciate that multiple accelerator units may be connected together to achieve higher acceleration energies than those possible using a single accelerator unit. Some embodiments provide that a modular accelerator unit as described herein may include a conductive electrode that may operate as a high voltage terminal, an accelerator tube, a charging system, a voltage stabilization system, a negative ion or electron source and an insulator to restrict the flow of charge from the conductive electrode in the desired direction.

Brief reference is now made to FIG. 4, which is a schematic diagram of a single unit high current particle accelerator according to some embodiments of the present invention. Discussions of the charging system 104, the stabilization system 101 and the process ion source 20 are provided above and will not be repeated in the description of FIG. 4. Some embodiments provide that the conductive electrode 102 is within an electrical shield structure 130. The conductive electrode 102 may be spaced apart from the electrical shield using one or more insulating structures 134 and a dielectric material 132. Some embodiments provide that the dielectric material 132 is a solid material, a pressurized gas and/or free air at atmospheric pressure.

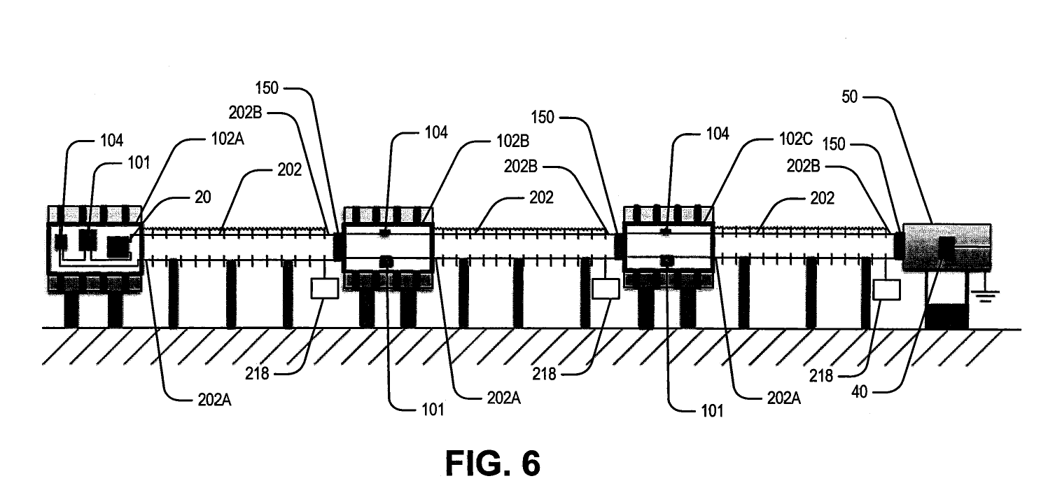

Reference is now made to FIG. 6, which is a schematic diagram of a high current particle accelerator system that includes multiple high current particle accelerator units according to some embodiments of the present invention. According to some embodiments of the present invention, the high current particle accelerator system may include multiple conductive electrodes 102 and multiple accelerator beam tubes 202 to define a beam current path from a process ion source 20 to a target 40. For example, a first conductive electrode 102A may include an interior in which the process ion source 20, a charging system 104 and a voltage stabilization system 101 are arranged.

An accelerator beam tube 202 may include a receiving end 202A that is galvanically coupled to the conductive electrode 102. A negative ion or electron source 218 may be connected to a transmitting end 202B of the accelerator beam tube 202. The transmitting end 202B maybe coupled to a second conductive electrode 102B via an insulator 150 that restricts the flow of charge from the conductive electrode in the desired direction. The second conductive electrode 102B may include an interior in which a charging system 104 and a voltage stabilization system 101 are arranged. In this manner, different ones of the conductive electrodes 102 may be charged independent of one another.

Another accelerator beam tube 202 may include a receiving end 202A that is galvanically coupled to the second conductive electrode 102B. A negative ion or electron source (e.g., an earth ground connection) 218 may be connected to a transmitting end 202B of the accelerator beam tube 202. The transmitting end 202B maybe coupled to a third conductive electrode 102C via an insulator 150 that restricts the flow of charge from the conductive electrode 102C in the desired direction. The second conductive electrode 102C may include an interior in which a charging system 104 and a voltage stabilization system 101 are arranged.

Yet another accelerator beam tube 202 may include a receiving end 202A that is galvanically coupled to the third conductive electrode 102C. A negative ion or electron source 218 may be connected to a transmitting end 202B of the accelerator beam tube 202. The transmitting end 202B maybe coupled to a target chamber 50 via an insulator 150 that restricts the flow of charge from the target chamber 50 in the desired direction. The serial arrangement of multiple conductive electrodes 102A-C coupled to one another with accelerator beam tubes 202 provides a modular approach to a particle accelerator system 100. The multiple conductive electrodes 102A-C may be charged to a voltage that is sustainable using atmospheric air as a dielectric, which may reduce the need for costly, space intensive and complex vacuum chambers.

Although not expressly illustrated, some embodiments include a vacuum system that is configured to pull a high vacuum or greater within the interior of the process ion source, the charging ion source, the high voltage stabilization system, the accelerator beam tubes 202 and the target chamber 50. Some embodiments provide that the vacuum system includes multiple vacuum pumps that are configured to provide a higher vacuum pump down rate than a single vacuum pump may provide. In some embodiments, the process, charging and stabilization ion sources all share the same vacuum volume, however other embodiments provide that one or more of the process, charging and stabilization ion sources is in a vacuum volume that is separate from the other ones.

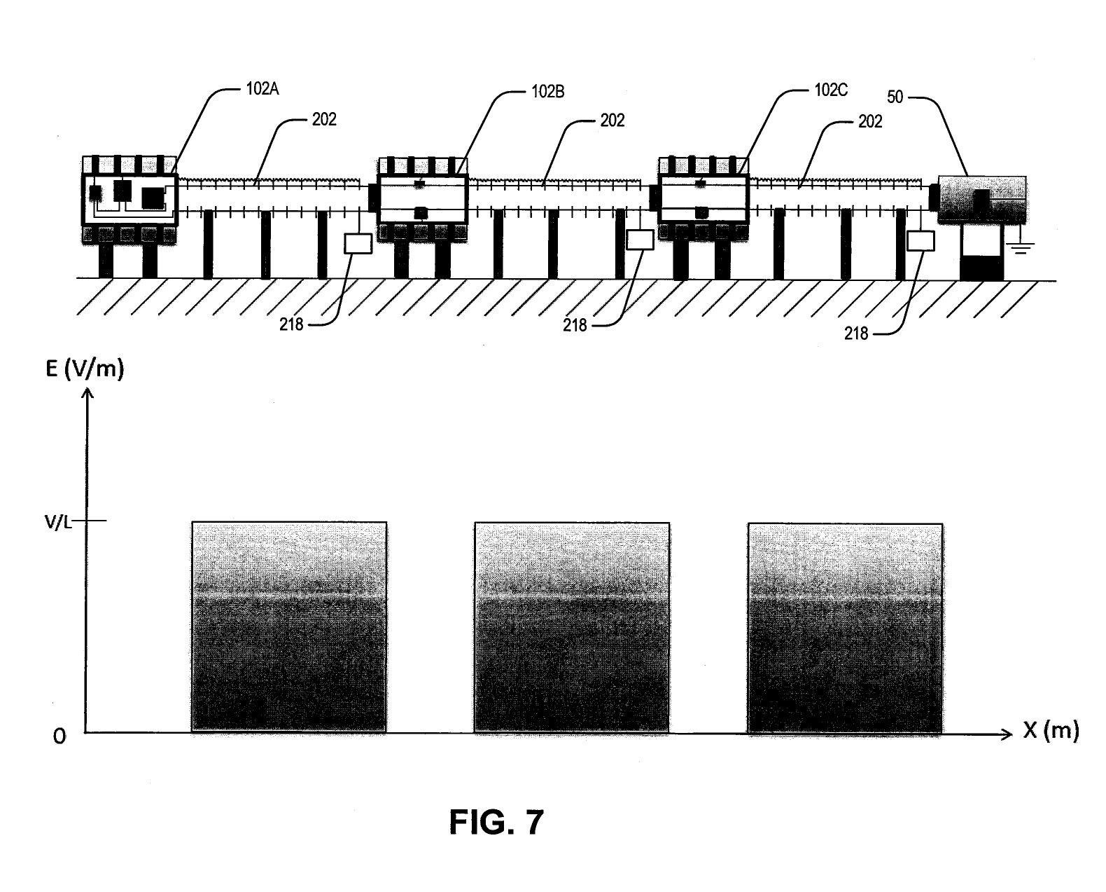

Reference is now made to FIG. 7, which is a schematic diagram of a high current particle accelerator system that includes multiple high current particle accelerator units as illustrated in FIG. 6 and a comparative graph illustrating the acceleration field as a function of position relative to the multiple high current particle accelerators according to some embodiments of the present invention. As illustrated, the particles being accelerated in the particle accelerators experience a significant energy increase in the accelerator beam tubes 202 each time they exit a corresponding one of the conductive electrodes 102A-C. In this manner, a particle accelerator system disclosed herein may be configured to include an amount of conductive electrodes and accelerator beam tubes necessary to achieve a desired level of beam energy such that each additional stage increases the beam energy.

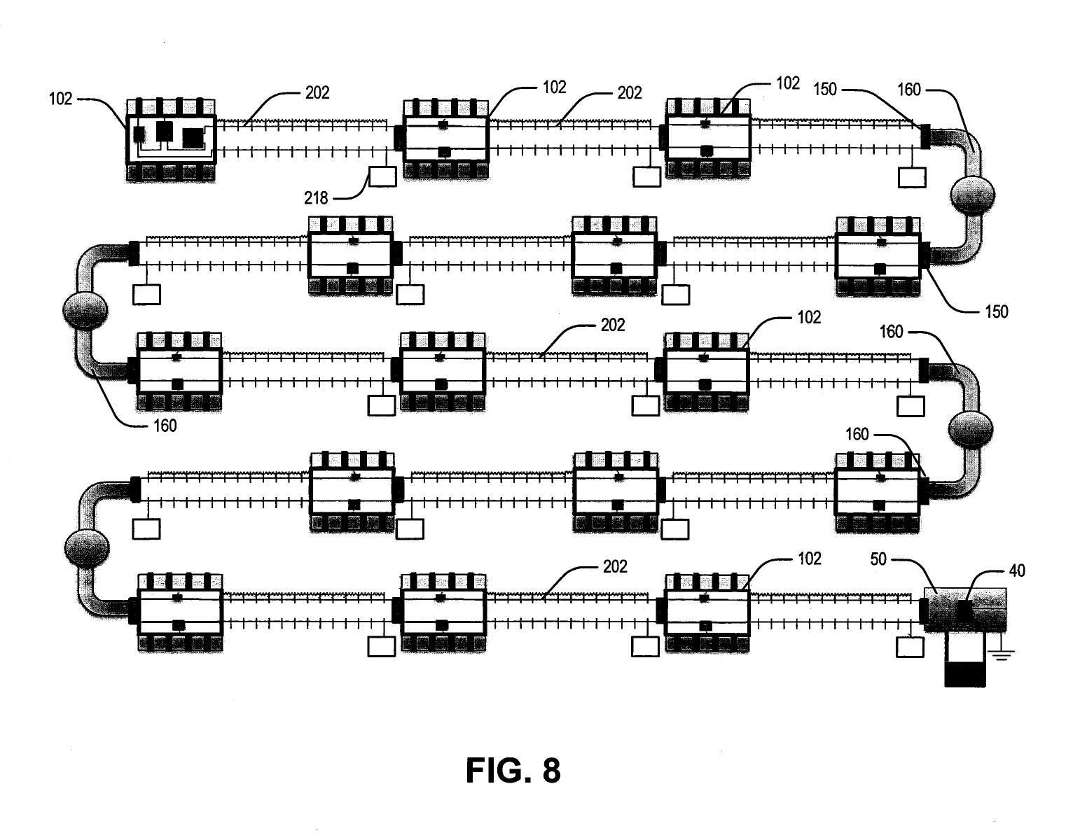

Although previous illustrations and descriptions have generally presented the particle accelerator beam system as a group of components arranged in a primarily linear arrangement, embodiments herein are not so limited. For example, brief reference is now made to FIG. 8, which is a schematic diagram of a high current particle accelerator system that includes multiple high current particle accelerator units in a non-linear arrangement according to some embodiments of the present invention. As illustrated, a particle accelerator system according to some embodiments includes multiple conductive electrodes 102, multiple charging systems and voltage stabilization systems corresponding to ones of the conductive electrodes 102, multiple accelerator beam tubes 202 between ones of the conductive electrodes 102 and a target chamber 50.

One or more bending magnets 160 may be coupled between an accelerator beam tube 202 and a conductive electrode 102 to provide a non-linear beam path. In this manner, high current particle accelerator systems as disclosed herein may be provided in facilities that may not include a single dimension length that is sufficient to arrange the system components in a single line. In some embodiments, the bending magnets 160 may be arranged between a grounded end of an accelerator beam tube 202 via an insulator 150 and a conductive electrode 102 via another insulator 150.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

That which is claimed is:

1. A system comprising:
a process ion source that is configured to emit ions;
a particle accelerator; and
a target,
wherein the particle accelerator comprises:
a conductive electrode that includes an interior space and that is configured to be charged to a high-voltage electrical potential;
a first charging device that is configured to deliver a charging current to the conductive electrode to charge the conductive electrode to a given polarity and a given magnitude;
a second charging device that is configured to generate a voltage stabilizing current to the conductive electrode that corresponds to an ion current of the process ion source that is within the interior space of the conductive electrode; and
an accelerator tube positioned between the process ion source and the target and that includes a particle receiving end that is galvanically coupled to the conductive electrode and a particle exit end that is opposite the particle receiving end and that is galvanically coupled to a negative ion or electron source, and
wherein the particle accelerator accelerates the ions emitted from the process ion source to produce accelerated ions that bombard the target.

2. The system according to claim 1, wherein the conductive electrode comprises a hollow metal shell, and
wherein the negative ion or electron source comprises an earth ground.

3. The system according to claim 1, wherein the accelerator tube comprises multiple step voltage divider that divides adjacent portions thereof into sections, each section having a reduced voltage in the direction towards the exits end of the accelerator tube.

4. The system according to claim 1, wherein the first charging device comprises a charging ion source that is configured to emit ions to provide the charging current to charge the conductive electrode.

5. The system according to claim 4, wherein the first charging device further comprises an ion implantation target that is positioned within the conductive electrode and that is configured to receive the ions emitted from the stabilization ion source.

6. The system according to claim 5, wherein the ion implantation target is galvanically coupled to the conductive electrode.

7. The system according to claim 1, wherein the second charging device comprises a stabilization ion source that is configured to emit ions responsive to the conductive electrode being charged by the first charging device.

8. The system according to claim 7, wherein the second charging device further comprises a stabilization ion implantation target that is positioned within the conductive electrode and that is configured to receive the ions emitted from the stabilization ion source.

9. The system according to claim 8, wherein the stabilization ion implantation target is galvanically coupled to the conductive electrode.

10. The system according to claim 8,
wherein the second charging device further comprises a conductive element that is conductively coupled between an interior surface of the conductive electrode and the ion implantation target, and
wherein charges flow from the conductive electrode to the ion implantation target via the conductive element responsive to the ion implantation target the ions from the stabilization ion source.

11. The system according to claim 10, wherein the conductive element comprises a conductive wire and/or carbon brushes.

12. The system according to claim 4, wherein the second charging device further comprises a stabilization ion transport volume that is between the stabilization ion source and the ion implantation medium and that is configured to provide a transport path for the ions from the stabilization ion source to the ion implantation medium.

13. The system according to claim 12,
wherein the ion transport volume comprises a structure that defines an evacuated space between the stabilization ion source and the ion implantation medium.

14. An apparatus comprising:
a conductive electrode that includes an interior space and that is configured to be charged to a high-voltage electrical potential;
a first charging device that is configured to deliver a charging current to the conductive electrode to charge the conductive electrode to a given polarity and a given magnitude;
a second charging device that is configured to generate a voltage stabilizing current to the conductive electrode that corresponds to an ion current of a process ion source that is within the interior space of the conductive electrode;
a conductive electrode receiving portion that is configured to be coupled to a first accelerator tube via a galvanically insulating structure that is operable to galvanically insulate the conductive electrode receiving portion from the first accelerator tube; and
a conductive electrode transmitting portion that is configured to be galvanically coupled to a second accelerator tube that is arranged opposite the conductive electrode receiving portion.

15. The apparatus according to claim 14, wherein the conductive electrode receiving portion is configured to receive atomic particles and the conductive electrode transmitting portion is configured to transmit atomic particles.

16. The apparatus according to claim 14, wherein the second charging device comprises:
a stabilization ion source that is positioned within an interior of the conductive electrode and that is configured to emit ions responsive to the conductive electrode being charged by the first charging device;
an ion implantation target that is configured to receive the ions emitted from the stabilization ion source;
an ion transport volume that is between the stabilization ion source and the ion implantation medium and that is configured to provide a transport path for the ions from the stabilization ion source to the ion implantation medium; and
a conductive element that is conductively coupled between an interior surface of the conductive electrode and the ion implantation target.

17. A system comprising:
a process ion source that is configured to emit ions;
a particle accelerator; and
a target,
wherein the particle accelerator comprises:
a plurality of conductive electrodes that are serially arranged to define a particle path between the process ion source and the target; and
a plurality of accelerator tubes arranged to further define the particle path between the process ion source, ones of the plurality of conductive electrodes and the target.

18. The system according to claim 17, wherein ones of the plurality of conductive electrodes include an interior space and are is configured to be charged to a high-voltage electrical potential, the system further comprising:
within ones of the plurality of conductive electrodes, a first charging device that is configured to deliver a charging current to the respective one of the plurality of conductive electrodes to charge the respective one of the plurality of conductive electrodes to a given polarity and a given magnitude and a second charging device that is configured to generate a voltage stabilizing current to the respective one of the plurality of conductive electrodes that corresponds to an ion current of a stabilizing process ion source that is within the interior space of the respective one of the plurality of conductive electrodes.

19. The system according to claim 17,
wherein the plurality of conductive electrodes includes a first conductive electrode and a second conductive electrode,
wherein the plurality of accelerator tubes includes a first accelerator tube and a second accelerator tube,
wherein the first conductive electrode includes an interior space that is configured to include the process ion source,
wherein the first accelerator tube includes is arranged between the first conductive electrode and the second conductive electrode, and
wherein the second accelerator tube is galvanically coupled to the second conductive electrode.

20. The system according to claim 19, wherein the first accelerator tube is galvanically coupled to the first conductive electrode and is coupled to the second conductive electrode via a first insulator.

21. The system according to claim 20, wherein the plurality of conductive electrodes includes a third conductive electrode,
wherein the second accelerator tube is coupled to the third conductive electrode via a second insulator.

22. The system according to claim 17, wherein ones of the plurality of conductive electrodes are configured to be charged to a high-voltage electrical potential, and
wherein the high-voltage electrical potential is sustainable in free space based on a dielectric constant corresponding to air.

23. A method comprising:
providing a charging current to a conductive electrode in a high current particle accelerator system using a charging ion source; and
providing a voltage stabilization current to the conductive electrode using a stabilization ion source that is different from the charging ion source.

24. The method according to claim 23, wherein the charging current comprises a current in a range from about 1 μA to about 150 μA, and
wherein the voltage stabilization current comprises a current in a range of 1 A to about 100 A.
